(19) United States
(12) Patent Application Publication
(10) Pub. No.: US 2022/0410572 A1
(43) Pub. Date: Dec. 29, 2022

(54) METHOD FOR PREHEATING SUBSTRATE TREATING APPARATUS AND COMPUTER PROGRAM FOR THE SAME

(71) Applicant: SEMES CO., LTD., Chungcheongnam-do (KR)

(72) Inventors: Cheon Su Cho, Gyeonggi-do (KR); Woo Young Ko, Chungcheongnam-do (KR)

(21) Appl. No.: 17/849,838

(22) Filed: Jun. 27, 2022

(30) Foreign Application Priority Data
Jun. 28, 2021 (KR) 10-2021-0083990

(51) Int. Cl. B41J 2/165; C23C 16/02; C23C 16/46; C23C 16/52; C23C 16/458; B41J 11/00

(52) U.S. Cl. CPC B41J 2/1652; C23C 16/0209; C23C 16/46; C23C 16/52; C23C 16/4583; B41J 11/0015; H01L 21/6715

(57) ABSTRACT

Disclosed are a method for preheating a substrate treating apparatus capable of shortening a preheating time and simultaneously performing a maintenance operation, and a computer program for the same. The method includes setting a parameter related to preheating of a preheating target component among components constituting the substrate treating apparatus; and preheating the preheating target component based on the set parameter, wherein a movement range of the preheating target component is limited to a value within a movable range.

### CROSS-REFERENCE TO RELATED APPLICATION

This application claims priority from Korean Patent Application No. 10-2021-0083990 filed on Jun. 28, 2021, in the Korean Intellectual Property Office, and all the benefits accruing therefrom under 35 U.S.C. 119, the contents of which in its entirety are herein incorporated by reference.

### BACKGROUND

### Field

The present disclosure relates to a method for preheating a substrate treating apparatus and a computer program for the same. More particularly, the present disclosure relates to a method for preheating a substrate treating apparatus used for printing a substrate, and a computer program for the same.

### Description of Related Art

When performing a printing process (for example, RGB patterning) on a transparent substrate to manufacture a display device such as a LCD panel, a PDP panel, and a LED panel, printing equipment having an inkjet head unit may be used.

### SUMMARY

In the printing equipment as a large facility, a slight temperature rise may occur due to an internal heating element during an operation of the facility. This may cause a positional variation in the equipment. Thus, in a prior art, in order to create the same environment under a constant operation condition, after dry run is performed, a main process is performed.

However, this approach has following problems. First, it takes a lot of time to complete the dry run. This may delay substrate printing to reduce productivity. Second, a MT operation such as head care may not be performed during the dry run.

A purpose to be achieved in accordance with the present disclosure is configured to provide a method for preheating a substrate treating apparatus capable of shortening a preheating time and simultaneously performing a maintenance operation during the preheating, and a computer program for the same.

Purposes in accordance with the present disclosure are not limited to the above-mentioned purpose. Other purposes and advantages in accordance with the present disclosure as not mentioned above may be understood from following descriptions and more clearly understood from embodiments in accordance with the present disclosure. Further, it will be readily appreciated that the purposes and advantages in accordance with the present disclosure may be realized by features and combinations thereof as disclosed in the claims.

A first aspect of the present disclosure to achieve the purpose provides a method for preheating a substrate treating apparatus, the method comprising: setting a parameter related to preheating of a preheating target component among components constituting the substrate treating apparatus; and preheating the preheating target component based on the set parameter, wherein a movement range of the preheating target component is limited to a value within a movable range.

In one implementation of the first aspect, the preheating target component includes an inkjet head unit for ejecting a substrate treating liquid onto a substrate.

In one implementation of the first aspect, the method further comprises performing maintenance on the inkjet head unit to correct an ejection point of a substrate treating liquid from the inkjet head unit, wherein the maintenance is performed simultaneously with the preheating.

In one implementation of the first aspect, the inkjet head unit reciprocates within an area where jetting of the inkjet head unit is performed.

In one implementation of the first aspect, the area where the jetting of the inkjet head unit is performed is determined based on a width of the substrate.

In one implementation of the first aspect, the area where the jetting of the inkjet head unit is performed is determined based on position information of both opposing ends of the substrate positioned on a stage, or based on position information of both opposing ends of the stage.

In one implementation of the first aspect, when the area where the jetting of the inkjet head unit is performed is determined based on the position information of the both opposing ends of the stage, the position information of the both opposing ends of the substrate are estimated based on position information of both opposing outermost air holes among air holes for levitating the substrate above the stage.

In one implementation of the first aspect, the inkjet head unit reciprocates in a minute manner.

In one implementation of the first aspect, the inkjet head unit moves in a micrometer or millimeter unit manner.

In one implementation of the first aspect, the parameter includes at least one selected from a group consisting of a movement distance of the inkjet head unit, a number of repetitions of the movement of the inkjet head unit, a movement time duration of the inkjet head unit, and a waiting time after the movement of the inkjet head unit.

In one implementation of the first aspect, the substrate treating apparatus includes a substrate printing apparatus, wherein the preheating is performed before performing printing on the substrate.

In one implementation of the first aspect, the preheating target component includes a gripper for griping the substrate.

In one implementation of the first aspect, the method further comprises determining whether to terminate the preheating of the preheating target component, based on a temperature around a motor for driving the preheating target component.

In one implementation of the first aspect, the determining of whether to terminate the preheating of the preheating target component includes: comparing the temperature around the motor with a reference temperature; and when the temperature around the motor is equal to or higher than the reference temperature, terminating the preheating of the preheating target component; or when the temperature around the motor is lower than the reference temperature, continuing the preheating of the preheating target component.

A second aspect of the present disclosure to achieve the purpose provides a method for preheating a substrate treating apparatus, the method comprising: setting a parameter related to preheating of an inkjet head unit for ejecting a substrate treating liquid onto a substrate; preheating the inkjet head unit based on the set parameter; and performing maintenance on the inkjet head unit to correct an ejection point of the substrate treating liquid from the inkjet head unit, wherein the maintenance is performed simultaneously with the preheating, wherein the inkjet head unit reciprocates within an area in which jetting of the inkjet head unit is performed.

A third aspect of the present disclosure to achieve the purpose provides a computer program included in a controller for controlling an operation of a substrate treating apparatus, the computer program comprising: a module configured to set a parameter related to preheating of a preheating target component among components constituting the substrate treating apparatus; and a module configured to cause preheating of the preheating target component to be performed based on the parameter, wherein a movement range of the preheating target component is limited to a value within a movable range.

In one implementation of the third aspect, the preheating target component includes one of an inkjet head unit for ejecting a substrate treating liquid onto the substrate and a gripper for holding the substrate.

In one implementation of the third aspect, the preheating target component is the inkjet head unit, wherein the computer program further comprises a module configured to cause maintenance to be performed on the inkjet head unit so as to correct an ejection point of the substrate treating liquid from the inkjet head unit, wherein the module related to the maintenance and the module related to the preheating are activated simultaneously.

In one implementation of the third aspect, the preheating target component is the inkjet head unit, wherein the inkjet head unit reciprocates within an area where jetting of the inkjet head unit is performed.

In one implementation of the third aspect, the inkjet head unit reciprocates in a minute manner, and in a micrometer or millimeter unit manner.

### BRIEF DESCRIPTION OF DRAWINGS

The above and other aspects and features of the present disclosure will become more apparent by describing in detail embodiments thereof with reference to the attached drawings, in which:

FIG. 1 is a diagram schematically showing an internal structure of a substrate treating apparatus according to one embodiment of the present disclosure;

FIG. 2 is a first illustrative diagram for illustrating a method for preheating a substrate treating apparatus according to one embodiment of the present disclosure;

FIG. 3 is a second illustrative diagram for illustrating a method for preheating a substrate treating apparatus according to one embodiment of the present disclosure;

FIG. 4 is a third illustrative diagram for illustrating a method for preheating a substrate treating apparatus according to one embodiment of the present disclosure;

FIG. 5 is a table diagram showing various parameter setting values for a method for preheating a substrate treating apparatus according to one embodiment of the present disclosure;

FIG. 6 is a flowchart sequentially illustrating steps of a method for preheating a substrate treating apparatus according to one embodiment of the present disclosure; and

FIG. 7 is a fourth illustrative diagram for illustrating a method for preheating a substrate treating apparatus according to one embodiment of the present disclosure.

### DETAILED DESCRIPTIONS

For simplicity and clarity of illustration, elements in the figures are not necessarily drawn to scale. The same reference numbers in different figures represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the figures is turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

The present disclosure relates to a substrate treating apparatus preheating method which may shorten a preheating time and simultaneously perform a maintenance operation during preheating, and a computer program for the same. Hereinafter, the present disclosure will be described in detail with reference to drawings and the like.

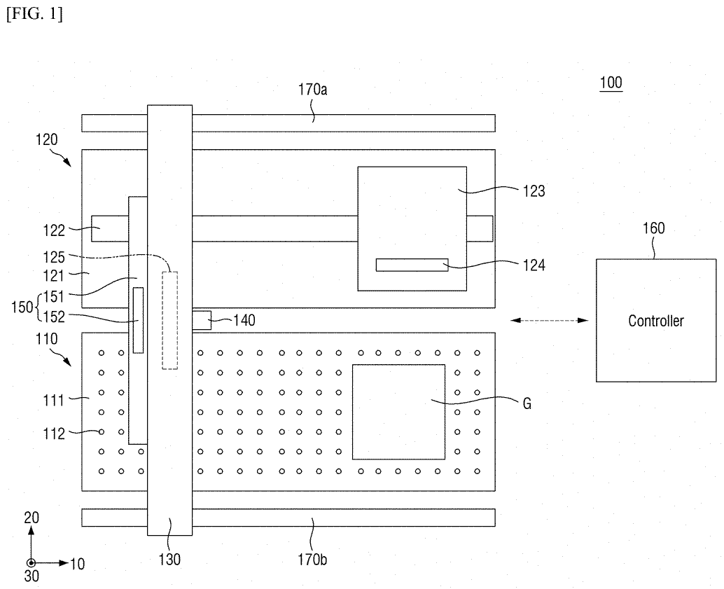

FIG. 1 is a diagram schematically showing an internal structure of a substrate treating apparatus according to one embodiment of the present disclosure.

According to FIG. 1, a substrate treating apparatus 100 may be configured to include a substrate support unit 110, a maintenance unit 120, a gantry unit 130, an inkjet head unit 140, a substrate treating liquid supply unit 150, and controller 160.

The substrate treating apparatus 100 treats a substrate G (for example, a glass substrate) used for manufacturing a display device. This substrate treating apparatus 100 may be implemented as a printing facility for ejecting a substrate treating liquid on the substrate G using the inkjet head unit 140 or may be implemented as a circulation system inkjet facility to prevent clogging of a nozzle due to the substrate treating liquid.

The substrate support unit 110 supports the substrate G while a PT operation is performed on the substrate G. This substrate support unit 110 may support the substrate Gin a non-contact scheme. The substrate support unit 110 may support the substrate G while levitating the substrate G above a base, for example, using air. However, the present embodiment is not limited thereto. The substrate support unit 110 is also capable of supporting substrate G in a contact scheme. The substrate support unit 110 may support the substrate G using, for example, a support member having a seat face on which the substrate is mounted.

As used herein, the PT operation refers to an operation of printing a substrate treating liquid on the substrate G. The substrate treating liquid refers to a chemical liquid used for printing treatment on the substrate G. The substrate treating liquid may be, for example, QD (Quantum Dot) ink containing ultrafine semiconductor particles therein.

When the substrate support unit 110 supports the substrate G using the air, the substrate support unit 110 may be configured to include a first stage 111 and air holes 112.

The first stage 111 may act as a base which is constructed so that the substrate G may be seated thereon. The air hole 112 may extend through the first stage 111, and may include a plurality of air holes arranged in a PT zone of the first stage 111.

The air holes 112 may inject air in an upward direction (a third direction 30) from the first stage 111. Thus, the air holes 112 may levitate the substrate G seated on the first stage 111 into the air.

In one example, although not shown in FIG. 1, the substrate support unit 110 may further include a gripper. The gripper is configured to prevent the substrate G from deviating out of the first stage 111 when the substrate moves along a length direction (a first direction 10) of the first stage 111. The gripper may grip the substrate G to prevent the substrate from deviating out of the first stage 111. When the substrate G moves, the gripper may slide along a guide rail (not shown) while holding the substrate G.

The maintenance unit 120 measures an ejection position (that is, a collision point) of the substrate treating liquid onto the substrate G, and detects whether the substrate treating liquid has been ejected, and the like. The maintenance unit 120 may measure the ejection position of the substrate treating liquid from each of a plurality of nozzles of the inkjet head unit 140, and detect whether the substrate treating liquid has been ejected from each of a plurality of nozzles of the inkjet head unit 140, etc. The measurement and detection results may be constructed to the controller 160.

The maintenance unit 120 may be configured to include a second stage 121, a third guide rail 122, a first plate 123, a calibration board 124, and a vision module 125.

Like the first stage 111, the second stage 121 may act as a base. The second stage may be arranged side by side with the first stage 111. The second stage 121 may be constructed to have the same size as that of the first stage 111, or may be constructed to have a size smaller or larger than that of the first stage 111. The second stage 121 may include an MT zone on a top face thereof.

The third guide rail 122 guides a movement path of the first plate 123. The third guide rail 122 may be disposed on the second stage 121 and may be embodied as at least one line structure extending along a length direction (the first direction 10) of the second stage 121. The third guide rail 122 may be implemented as, for example, an LM guide system (a Linear Motor Guide System).

In one example, although not shown in FIG. 1, the maintenance unit 120 may further include a fourth guide rail. The fourth guide rail guides the movement path of the first plate 123 as the third guide rail 122 does. The fourth guide rail may be embodied as at least one line structure extending along a length direction (the first direction 10) of the second stage 121 and may be disposed on the second stage 121. The fourth guide rail may also be implemented as an LM guide system as the third guide rail 122 may.

The first plate 123 may move on the second stage 121 and along the third guide rail 122 and/or the fourth guide rail. The first plate 123 may move in a parallel manner to the substrate G along the third guide rail 122, and may move toward or away from the substrate G along the fourth guide rail.

The calibration board 124 is configured for measuring the ejection position of the substrate treating liquid on the substrate G. This calibration board 124 may include an alignment mark, a graduated ruler, etc. and be installed on the first plate 123, and may extend along a length direction (the first direction 10) of the first plate 123.

The vision module 125 acquires image information about the substrate G to measure the ejection position of the substrate treating liquid, whether the substrate treating liquid has been ejected, and the like. The vision module 125 may include an area scan camera, a line scan camera, etc. and may acquire image information about the substrate G in real time. In one example, the vision module 125 may obtain and provide information about the calibration board 124 along with information about the substrate G onto which the substrate treating liquid has been ejected.

The vision module 125 may be disposed on a side or a bottom of the gantry unit 130 to image the substrate G or the like. The vision module 125 may be installed, for example, in a manner attached to a side of the inkjet head unit 140. However, the present embodiment is not limited thereto. The vision module 125 may be disposed on the first plate 123. In one example, a plurality of vision modules 125 may be provided in the substrate treating apparatus 100. The vision module may be fixedly installed or movably installed.

The gantry unit 130 is configured to support the inkjet head unit 140. The gantry unit 130 may be disposed on a top face of the first stage 111 and the second stage 121 so that the inkjet head unit 140 may eject the substrate treating liquid on the substrate G.

The gantry unit 130 may be disposed on the first stage 111 and the second stage 121 such that a length direction of the gantry unit 130 corresponds to the width direction 20 of the first stage 111 and the second stage 121. The gantry unit 130 may move along a first guide rail 170a and a second guide rail 2nd 170b, and in the length direction (the first direction 10) of each of the first stage 111 and the second stage 121. In one example, the first guide rail 170a and the second guide rail 170b may be respectively disposed out of the first stage 111 and the second stage 121 while the first stage 111 and the second stage 121 are disposed therebetween. The first guide rail 170a and the second guide rail 170b may extend along the length direction (the first direction 10) of each of the first stage 111 and the second stage 121.

In one example, although not shown in FIG. 1, the substrate treating apparatus 100 may further include a gantry driving unit. The gantry driving unit may move the gantry unit 130 along the first guide rail 170a and the second guide rail 170b. The gantry driving unit may be installed inside the gantry unit 130, and may be configured to include a first driving module (not shown) and a second driving module (not shown). The first driving module and the second driving module may be respectively provided at both opposing ends of the gantry unit 130, and may move the gantry unit 130 in a sliding manner along the first guide rail 170a and the second guide rail 170b.

The inkjet head unit 140 ejects the substrate treating liquid in a form of a droplet on the substrate G. This inkjet head unit 140 may be disposed at a side or a bottom of the gantry unit 130.

At least one inkjet head unit 140 may be installed on the gantry unit 130. When a plurality of inkjet head units 140 are installed on the gantry unit 130, the plurality of inkjet head units 140 may be arranged in a line along a length direction (the second direction 20) of the gantry unit 130.

The inkjet head unit 140 may move along the length direction (the second direction 20) of the gantry unit 130 so as to reach a desired point on the substrate G. However, the present embodiment is not limited thereto. The inkjet head unit 140 may move along a vertical dimension direction (the third direction 30) of the gantry unit 130, and/or rotate in a clockwise or counterclockwise direction.

In one example, the inkjet head unit 140 may be installed so as to be fixed to the gantry unit 130. In this case, the gantry unit 130 may be constructed to be movable.

In one example, although not shown in FIG. 1, the substrate treating apparatus 100 may further include an inkjet head driving unit. The inkjet head driving unit is configured to move the inkjet head unit 140 in a straight line or rotate the inkjet head unit 140 in a clockwise or counterclockwise direction. When the substrate treating apparatus 100 is configured to include the plurality of inkjet head units 140, the number of the inkjet head driving units corresponds to the number of inkjet head units 140 so as to independently and respectively move or rotate the plurality of inkjet head units 140. The inkjet head driving units may be disposed in the substrate treating apparatus 100. In one example, a single inkjet head driving unit may be provided in the substrate treating apparatus 100 so as to collectively drive the plurality of inkjet head units 140.

In one example, although not shown in FIG. 1, the inkjet head unit 140 may be configured to include a nozzle plate, a plurality of nozzles, a piezoelectric element, and the like. The nozzle plate constitutes a body of the inkjet head unit 140. A plurality of nozzles (for example, 128, 256, . . . , nozzles) may be arranged in multiple rows and columns while being spaced from each other by a certain spacing and may be defined in a bottom of the nozzle plate. This piezoelectric element may be disposed in the nozzle plate. The number of the piezoelectric element may correspond to the number of nozzles. When the inkjet head unit 140 is configured in this manner, the unit 140 may eject the substrate treating liquid onto the substrate G through the nozzle under an operation of the piezoelectric element.

In one example, the inkjet head unit 140 may be configured to independently control an amount of ejection of the substrate treating liquid through each of nozzles based on voltage applied to each of the piezoelectric elements.

The substrate treating liquid supply unit 150 supplies ink to the inkjet head unit 140. This substrate treating liquid supply unit 150 may be configured to include a storage tank 151 and a pressure control module 152.

The storage tank 151 is configured to store the substrate treating liquid therein, and the pressure control module 152 is configured to adjust an internal pressure of the storage tank 151. The storage tank 151 may supply an appropriate amount of the substrate treating liquid to the inkjet head unit 140 based on the pressure controlled by the pressure control module 152.

The controller 160 is configured to perform maintenance on the inkjet head unit 140. The controller 160 corrects the substrate treating liquid ejection position from each nozzle of the inkjet head unit 140 based on the measurement result of the maintenance unit 120, or detects a defective nozzle (that is, a nozzle that does not eject the substrate treating liquid) among a plurality of nozzles and controls a cleaning unit (not shown) to perform a cleaning procedure on the defective nozzle. To this end, the controller 160 may control an operation of each of the components constituting the substrate treating apparatus 100.

The controller 160 may include a process controller, a control program, an input module, an output module (or a display module), a memory module, and the like and be implemented as a computer or a server. In this regard, the process controller may include a microprocessor that executes a control function on each of the components constituting the substrate treating apparatus 100. This control program may execute various treatments of the substrate treating apparatus 100 under the control of the process controller. The memory module stores therein programs (that is, treatment recipes) for executing various treatments of the substrate treating apparatus 100 based on various data and treatment conditions.

In one example, although not shown in FIG. 1, the substrate treating apparatus 100 may further include a nozzle inspection unit. The nozzle inspection unit is configured to determine whether there is an abnormality on each of the nozzles installed in the inkjet head unit 140. The nozzle inspection unit may determine whether there is an abnormality in the nozzle based on, for example, an optical inspection result.

Hereinafter, a method for preheating the substrate treating apparatus 100 which may be capable of shortening the preheating time and simultaneously performing the maintenance operation will be described.

The method for preheating the substrate treating apparatus 100 may be performed before the substrate treating apparatus 100 prints the treating liquid on the substrate G. The method for preheating the substrate treating apparatus 100 may be performed under control of the controller 160. Specifically, the method for preheating the substrate treating apparatus 100 may be performed based on a computer program (a control program) received in the controller 160.

The controller 160 may control the operation of each of the components constituting the substrate treating apparatus 100 so as to preheat the substrate treating apparatus 100. Hereinafter, this control will be described.

When the dry run is performed to preheat the substrate treating apparatus 100, each of the components of the substrate treating apparatus 100 moves along all areas on a stroke. Hereinafter, a case in which the inkjet head unit 140 performs the dry run will be described by way of example.

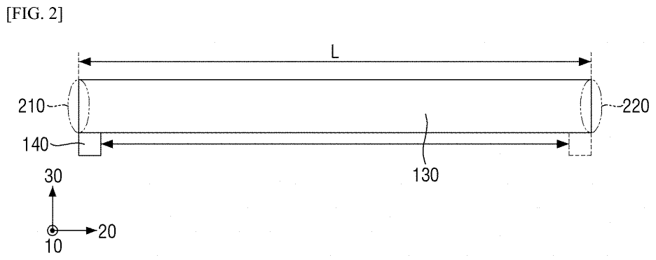

When the dry run is performed to preheat a motor that drives the inkjet head unit 140, the inkjet head unit 140 may reciprocate from one end 210 to the other end 220 of the gantry unit 130 and along the length direction (the second direction 20) of the gantry unit 130 as shown in FIG. 2. In this case, a movement range of the inkjet head unit 140 may be a length L of the gantry unit 130. FIG. 2 is a first illustrative diagram for illustrating a method for preheating a substrate treating apparatus according to one embodiment of the present disclosure.

However, when the inkjet head unit 140 reciprocates in this way, the MT operation such as the head care, etc. may not be performed while preheating the motor that drives the inkjet head unit 140. Further, when performing a printing process on the substrate G, the dry run operation should be stopped and then the MT operation should be performed and then the printing process must be started. Thus, this scheme consumes a lot of time before the printing process starts.

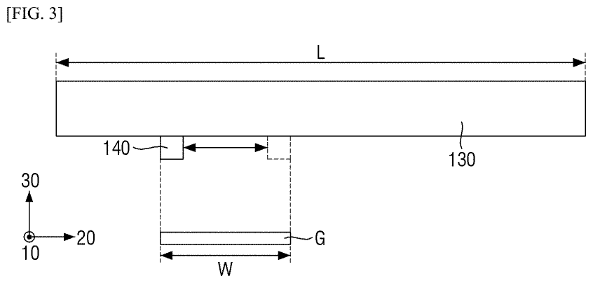

In this embodiment, in order to solve such a problem, the inkjet head unit 140 may reciprocate within an area in which jetting of the inkjet head unit 140 is performed during the motor aging. That is, the inkjet head unit 140 may reciprocate along the length direction (the second direction 20) of the gantry unit 130 and within a width range W of the substrate G as shown in FIG. 3. FIG. 3 is a second illustrative diagram for illustrating a method for preheating a substrate treating apparatus according to one embodiment of the present disclosure.

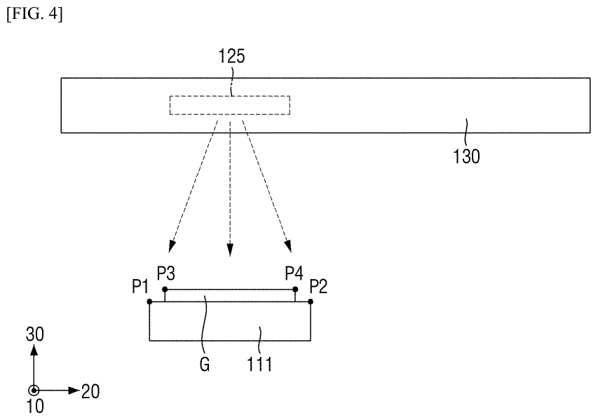

The substrate G may be disposed on the first stage 111 for a maintenance process. In this case, the vision module 125 may measure position information P3 and P4 of both opposing ends in a width direction of the substrate G located on the first stage 111 as shown in FIG. 4. The controller 160 may determine a movement range of the inkjet head unit 140 based on the measurement results P3 and P4 of the vision module 125. Thus, because the movement range of the inkjet head unit 140 does not deviate out of the substrate G, the maintenance procedure may be performed while preheating the motor that drives the inkjet head unit 140. FIG. 4 is a third illustrative diagram for illustrating a method for preheating a substrate treating apparatus according to one embodiment of the present disclosure.

In one example, in this embodiment, the vision module 125 may measure the position information P1 and P2 of both opposing ends in the width direction of the first stage 111. The controller 160 may estimate the position information P3 and P4 of both opposing ends in the width direction of the substrate G, based on the measurement result P1 and P2 of the vision module 125. In this case, the controller 160 may know in advance distance differences respectively between the position information P1 and P2 of both opposing ends of the first stage 111 and the position information P3 and P4 of both opposing ends of the substrate G.

The distance differences P1-P3 and P2-P4 respectively between the position information P1 and P2 of both opposing ends of the first stage 111 and the position information P3 and P4 of both opposing ends of the substrate G may be stored in a memory module of the controller 160. The distance differences P1-P3 and P2-P4 respectively between the position information P1 and P2 of both opposing ends of the first stage 111 and the position information P3 and P4 of both opposing ends of the substrate G may be calculated based on the air holes 112 formed in the first stage 111. That is, position information of the air hole 112 located at each of both opposing outermost points in the width direction of the first stage 111 among the plurality of air holes 112 formed in the first stage 111 may correspond to each of the position information P3 and P4 of both opposing ends in the width direction of the substrate G. Thus, the distance differences P1-P3 and P2-P4 respectively between the position information P1 and P2 of both opposing ends of the first stage 111 and the position information P3 and P4 of both opposing ends of the substrate G may be estimated based on distance differences respectively between the position information P1 and P2 of both opposing ends of the first stage 111 and the position information of the air holes 112 located at the both opposing outermost points in the width direction of the first stage 111 among the plurality of air holes 112 formed in the first stage 111.

In one example, when the dry run is performed to preheat the substrate treating apparatus 100, it takes a lot of time to complete the dry run. Thus, there is a problem in that the productivity of the product is lowered.

In this embodiment, in order to solve this problem, the movement of the inkjet head unit 140 may be controlled based on various parameter setting values related to optimization of the preheating, thereby obtaining an effect of improving the product productivity without wasting the preheating time. Hereinafter, this control will be described.

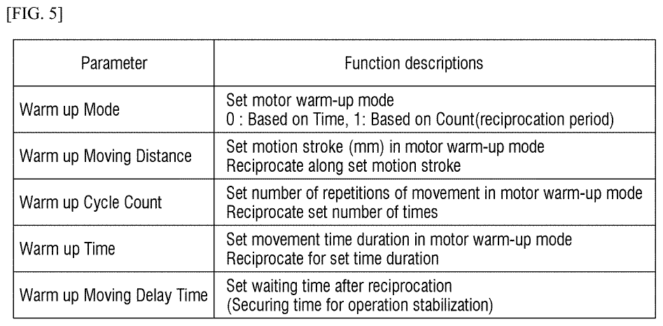

FIG. 5 is a table diagram showing various parameter setting values for a method for preheating a substrate treating apparatus according to one embodiment of the present disclosure. Following descriptions refer to FIG. 5.

When it is determined that preheating of the inkjet head unit 140 is necessary, the controller 160 may set a warm-up mode. In this case, the controller 160 may set a first warm-up mode based on a time and set a second warm-up mode based on a reciprocation period.

When the controller 160 sets the second warm-up mode based on the reciprocation period, the reciprocation period may be set based on a distance or the reciprocation period may be set based on a time. For example, when the movement range of the inkjet head unit 160 is determined based on the width of the substrate G, the controller 160 may set the reciprocation period using this movement range as the distance. Further, the controller 160 may determine a time consumed to reciprocate along the movement range, and may set the reciprocation period based on this time.

After activating the warm-up mode, the controller 160 may set details of the warm-up mode based on a movement distance of the inkjet head unit 140, the number of repetitions of the movement of the inkjet head unit 140, a movement time duration of the inkjet head unit 140, a waiting time of the inkjet head unit 140, etc.

When setting the detail (Warm up Moving Distance) of the warm-up mode based on the movement distance of the inkjet head unit 140, the controller 160 may set a motion stroke in both opposing directions around a reference position. In this regard, the motion stroke in both opposing directions around the reference position may be within the width range of the substrate G.

Further, when setting the detail (Warm up Cycle Count) of the warm-up mode based on the number of repetitions of the movement of the inkjet head unit 140, the controller 160 may set the number of repetitions of the reciprocating count. In this regard, the reciprocation period may be based on the movement range of the inkjet head unit 140 based on the width of substrate G.

Further, when setting the detail (Warm up Time) of the warm-up mode based on the movement time duration of the inkjet head unit 140, the controller 160 may set a time duration for which the inkjet head unit 140 operates.

Further, setting the detail (Warm up Moving Delay Time) of the warm-up mode based on the waiting time of the inkjet head unit 140, the controller 160 may set a waiting time after the inkjet head unit 140 operates and before a next operation. The waiting time of the inkjet head unit 140 refers to a time required for stabilizing the operation of the inkjet head unit 140.

The controller 160 may set the warm-up mode of the inkjet head unit 140 based on a combination of a plurality of setting values among the various parameter setting values. For example, the controller 160 may set the movement distance of the inkjet head unit 140 and then set the number of repetitions of the inkjet head unit 140. In this embodiment, the controller may additionally set the waiting time of the inkjet head unit 140. Further, after the controller 160 sets the movement distance of the inkjet head unit 140, the controller may sequentially set the movement time duration and the waiting time of the inkjet head unit 140.

As described above with reference to FIG. 1 to FIG. 5, the method for preheating the substrate treating apparatus 100 according to the present embodiment is configured for preheating the substrate treating apparatus 100 to an optimal state before starting the printing process, such that the preheating time via the dry run may be shortened or eliminated. In this method, the MT operation, that is, the head care which could not be performed during the execution of the dry run may be performed.

The dry run refers to a scheme for preheating the motor by applying a current value while a servo is stopped. In the dry run, Servo On/Off operation is required. Calibration of a reference point of the equipment is required. Therefore, there is a high possibility that the motor may operate excessively during the dry run.

On the contrary, in the method for preheating the substrate treating apparatus 100 according to the present embodiment, the motor may be preheated while minute movement occurs in a (+) direction and a (−) direction around a reference position of the motor. While the motor is preheated, the MT operation may be executed. Further, the method for preheating the substrate treating apparatus 100 according to the present embodiment may shorten a printing preparation operation before the printing process starts, and may shorten the preheating time.

In one example, the method for preheating the substrate treating apparatus 100 as described with reference to FIG. 1 to FIG. 5 may be applied to not only a case in which the inkjet head unit 140 reciprocates in the second direction 20 for preheating the inkjet head unit 140, but also a case in which the gripper reciprocates in the first direction 10 for preheating the gripper.

Next, individual steps of the method for preheating the substrate treating apparatus 100 will be described.

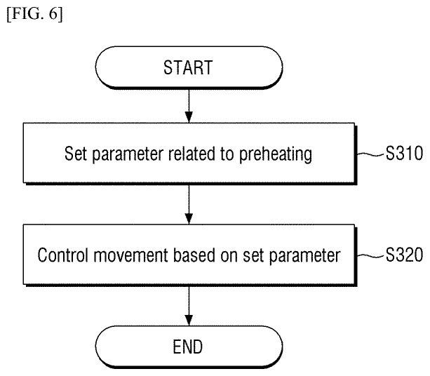

FIG. 6 is a flowchart sequentially illustrating steps of a method for preheating a substrate treating apparatus according to one embodiment of the present disclosure. The following description is based on an example in which the inkjet head unit 140 is preheated and refers to FIG. 6.

First, the controller 160 sets the parameter values related to the preheating of the inkjet head unit 140 in S310. The controller 160 may set the parameter values related to the preheating of the inkjet head unit 140, based on at least one selected from the movement distance of the inkjet head unit 140, the number of repetitions of the movement of the inkjet head unit 140, the movement time duration of the inkjet head unit 140, and the waiting time of the inkjet head unit 140. This has been described above with reference to FIG. 5. Thus, a detailed description thereof is omitted.

When the parameter values in relation to the preheating of the inkjet head unit 140 has been set, the controller 160 controls the movement of the inkjet head unit 140 based on the set parameter values in S320.

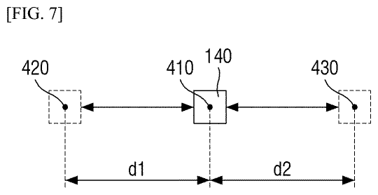

The inkjet head unit 140 may move minutely to a second point 420 positioned in the (+) direction around a first point 410 and to a third point 430 positioned in the (−) direction around the first point 410 as shown in FIG. 7. In this regard, a distance d1 between the first point 410 and the second point 420 may have an order of μm to mm (e.g., 5 mm). Similarly, a distance d2 between the first point 410 and the third point 430 may have an order of μm to mm (e.g., 5 mm). That is, the inkjet head unit 140 may reciprocate between the first point 410 and the second point 420, between the first point 410 and the third point 430, between the second point 420 and the third point 430 at a speed of μm to mm per second (μm/sec to mm/sec).

In one example, the (+) direction refers to a direction from a center of the gantry unit 130 to one end 210 thereof in the length direction (the second direction 20) of the gantry unit 130, while the (−) direction refers to a direction from the center of the gantry unit 130 to the other end 220 thereof in the length direction (the second direction 20) of the gantry unit 130. Alternatively, the (−) direction refers to a direction from a center of the gantry unit 130 to one end 210 thereof in the length direction (the second direction 20) of the gantry unit 130, while the (+) direction refers to a direction from the center of the gantry unit 130 to the other end 220 thereof in the length direction (the second direction 20) of the gantry unit 130. FIG. 7 is a fourth illustrative diagram for illustrating a method for preheating a substrate treating apparatus according to one embodiment of the present disclosure.

In one example, when the movements of the inkjet head unit 140 based on all of the set parameter values have been completed, the controller 160 may determine that the preheating of the inkjet head unit 140 has been completed. However, the present embodiment is not limited thereto. The controller 160 may measure a temperature around the motor that drives the inkjet head unit 140, and may compare the measured temperature with a reference temperature and may determine whether the preheating of the inkjet head unit 140 has been completed, based on the comparing result.

Specifically, when it is determined that the temperature around the motor is equal to or higher than the reference temperature, the controller 160 may terminate the preheating of the motor. When it is determined that the temperature around the motor is lower than the reference temperature, the controller 160 may continue the preheating of the motor. In this regard, when the movements of the inkjet head unit 140 based on all of the set parameter values have been completed, the process may return to S610 in which the parameters may be set again. When the movement of the inkjet head unit 140 based on at least one of the set parameter values has not been completed, the movement of the inkjet head unit 140 may be performed based on the parameter value as not yet used. In the above description, the reference temperature refers to a temperature around the motor when the preheating of the motor has been completed.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure. the scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. A method for preheating a substrate treating apparatus, the method comprising:
setting a parameter related to preheating of a preheating target component among components constituting the substrate treating apparatus; and
preheating the preheating target component based on the set parameter,
wherein a movement range of the preheating target component is limited to a value within a movable range.

2. The method of claim 1, wherein the preheating target component includes an inkjet head unit for ejecting a substrate treating liquid onto a substrate.

3. The method of claim 2, wherein the method further comprises performing maintenance on the inkjet head unit to correct an ejection point of a substrate treating liquid from the inkjet head unit,
wherein the maintenance is performed simultaneously with the preheating.

4. The method of claim 2, wherein the inkjet head unit reciprocates within an area where jetting of the inkjet head unit is performed.

5. The method of claim 4, wherein the area where the jetting of the inkjet head unit is performed is determined based on a width of the substrate.

6. The method of claim 4, wherein the area where the jetting of the inkjet head unit is performed is determined based on position information of both opposing ends of the substrate positioned on a stage, or based on position information of both opposing ends of the stage.

7. The method of claim 6, wherein when the area where the jetting of the inkjet head unit is performed is determined based on the position information of the both opposing ends of the stage, the position information of the both opposing ends of the substrate are estimated based on position information of both opposing outermost air holes among air holes for levitating the substrate above the stage.

8. The method of claim 4, wherein the inkjet head unit reciprocates in a minute manner.

9. The method of claim 8, wherein the inkjet head unit moves in a micrometer or millimeter unit manner.

10. The method of claim 2, wherein the parameter includes at least one selected from a group consisting of a movement distance of the inkjet head unit, a number of repetitions of the movement of the inkjet head unit, a movement time duration of the inkjet head unit, and a waiting time after the movement of the inkjet head unit.

11. The method of claim 1, wherein the substrate treating apparatus includes a substrate printing apparatus,
wherein the preheating is performed before performing printing on the substrate.

12. The method of claim 1, wherein the preheating target component includes a gripper for griping the substrate.

13. The method of claim 1, wherein the method further comprises determining whether to terminate the preheating of the preheating target component, based on a temperature around a motor for driving the preheating target component.

14. The method of claim 13, wherein the determining of whether to terminate the preheating of the preheating target component includes:
comparing the temperature around the motor with a reference temperature; and
when the temperature around the motor is equal to or higher than the reference temperature, terminating the preheating of the preheating target component; or
when the temperature around the motor is lower than the reference temperature, continuing the preheating of the preheating target component.

15. A method for preheating a substrate treating apparatus, the method comprising:
setting a parameter related to preheating of an inkjet head unit for ejecting a substrate treating liquid onto a substrate;
preheating the inkjet head unit based on the set parameter; and
performing maintenance on the inkjet head unit to correct an ejection point of the substrate treating liquid from the inkjet head unit,
wherein the maintenance is performed simultaneously with the preheating,
wherein the inkjet head unit reciprocates within an area in which jetting of the inkjet head unit is performed.

16. A computer program included in a controller for controlling an operation of a substrate treating apparatus, the computer program comprising:
a module configured to set a parameter related to preheating of a preheating target component among components constituting the substrate treating apparatus; and
a module configured to cause preheating of the preheating target component to be performed based on the parameter,
wherein a movement range of the preheating target component is limited to a value within a movable range.

17. The computer program of claim 16, wherein the preheating target component includes one of an inkjet head unit for ejecting a substrate treating liquid onto the substrate and a gripper for holding the substrate.

18. The computer program of claim 17, wherein the preheating target component is the inkjet head unit,
wherein the computer program further comprises a module configured to cause maintenance to be performed on the inkjet head unit so as to correct an ejection point of the substrate treating liquid from the inkjet head unit,
wherein the module related to the maintenance and the module related to the preheating are activated simultaneously.

19. The computer program of claim 17, wherein the preheating target component is the inkjet head unit,
wherein the inkjet head unit reciprocates within an area where jetting of the inkjet head unit is performed.

20. The computer program of claim 19, wherein the inkjet head unit reciprocates in a minute manner, and in a micrometer or millimeter unit manner.
